(19) United States
(12) Patent Application Publication
(10) Pub. No.: US 2026/0120778 A1
(43) Pub. Date: Apr. 30, 2026

(54) SEMICONDUCTOR MEMORY DEVICE

(71) Applicant: SK hynix Inc., Gyeonggi-do (KR)

(72) Inventors: Byoung Jun PARK, Gyeonggi-do (KR); Mu Sun KIM, Gyeonggi-do (KR); Joo Hyun PARK, Gyeonggi-do (KR)

(21) Appl. No.: 19/372,300

(22) Filed: Oct. 29, 2025

(30) Foreign Application Priority Data
Oct. 29, 2024 (KR) 10-2024-0149779

(51) Int. Cl. G11C 16/34; G11C 16/28; G11C 16/30

(52) U.S. Cl. CPC G11C 16/3418; G11C 16/28; G11C 16/30; G11C 16/3404

(57) ABSTRACT

A semiconductor memory device includes a die including a plurality of planes each having a plurality of memory cells, a plurality of temperature sensors arranged in the die and arranged to correspond to respective planes, and a temperature compensation circuit configured to generate, based on plane temperature values obtained from the plurality of temperature sensors respectively, a read control signal for performing a read operation on each of the plurality of plane.

### CROSS-REFERENCE TO RELATED APPLICATION

This patent document claims the priority and benefits of Korean patent application No. 10-2024-0149779, filed on Oct. 29, 2024, the disclosure of which is incorporated herein by reference in its entirety.

### TECHNICAL FIELD

The technology and embodiments of the present disclosure generally relate to a semiconductor memory device for storing data therein.

### BACKGROUND

A semiconductor memory device may include a plurality of memory cells for storing data therein. In addition, the semiconductor memory device may be classified into a nonvolatile memory device that can maintain stored data even when the power supply is interrupted, and a volatile memory device that does not preserve data when the power supply is interrupted.

The memory cells included in the nonvolatile memory device may have different operating characteristics depending on the usage environment such as temperature and/or the number of program/erase cycles. To prevent performance degradation of the nonvolatile memory device due to such changes in operating characteristics, an operating voltage corresponding to the temperature and/or the number of program/erase cycles needs to be provided to the memory cells.

### SUMMARY

Various embodiments of the present disclosure relate to a semiconductor memory device that performs a read operation corresponding to a temperature change in memory cells.

In accordance with an embodiment of the present disclosure, a semiconductor memory device may include a die including a plurality of planes each having a plurality of memory cells, a plurality of temperature sensors arranged in the die and arranged to correspond to respective planes, and a temperature compensation circuit configured to generate, based on plane temperature values obtained from the plurality of temperature sensors respectively, a read control signal for performing a read operation on each of the plurality of planes.

In accordance with another embodiment of the present disclosure, a semiconductor memory device may include a plurality of planes, each of which includes a plurality of memory cells, a plurality of temperature sensors arranged corresponding to the respective planes, a temperature compensation circuit configured to generate, based on plane temperature values obtained from the respective temperature sensors, a read bias voltage for performing a read operation on each of the plurality of planes, and a page buffer circuit configured to determine data by comparing a voltage level of a signal transmitted through a bit line connected to the plurality of planes with the read bias voltage.

In accordance with another embodiment of the present disclosure, a semiconductor memory device may include a plurality of planes, each of which includes a plurality of memory cells, a plurality of temperature sensors arranged to correspond to the respective planes, a temperature compensation circuit configured to generate, based on plane temperature values obtained from the respective temperature sensors, a voltage control signal for controlling levels of shift control voltages required to shift a threshold voltage distribution of the memory cells, and a voltage generator configured to generate the shift control voltage based on the voltage control signal.

It is to be understood that both the foregoing general description and the following detailed description of the present disclosure are illustrative and are intended to provide further description of the embodiments of the present disclosure as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1 is a block diagram illustrating a memory system based on some embodiments of the present disclosure.

FIG. 2 is a block diagram illustrating a memory device shown in FIG. 1 based on some embodiments of the present disclosure.

FIG. 3 is a schematic diagram illustrating a layout structure of temperature sensors shown in FIG. 2 based on some embodiments of the present disclosure.

FIG. 4 is a flowchart illustrating a temperature compensation method of a memory device based on some embodiments of the present disclosure.

FIG. 5 is a diagram illustrating operations according to operation S430 of FIG. 4 based on some embodiments of the present disclosure.

FIG. 6 is a diagram illustrating operations according to operation S440 of FIG. 4 based on some embodiments of the present disclosure.

FIG. 7 is a flowchart illustrating a temperature compensation method of a memory device based on some other embodiments of the present disclosure.

FIG. 8 is a diagram illustrating operations according to operation S720 of FIG. 7.

FIG. 9 is a schematic diagram illustrating a method for calculating a representative temperature value described in FIG. 8.

### DETAILED DESCRIPTION

The present disclosure provides embodiments and examples of a semiconductor memory device for storing data therein that may be used in configurations to substantially address one or more technical or engineering issues and to mitigate limitations or disadvantages encountered in some other semiconductor memory devices. Some embodiments of the present disclosure relate to a semiconductor memory device that performs a read operation corresponding to a temperature change in memory cells. In recognition of the issues above, the embodiments of the present disclosure provide a semiconductor memory device that can improve performance of a read operation by setting a read condition using temperature information obtained from a plurality of temperature sensors arranged adjacent to each plane of the semiconductor memory device.

Reference will now be made in detail to the embodiments of the present disclosure which are illustrated in the accompanying drawings. Wherever possible, the same reference numbers will be used throughout the drawings to refer to the same or like parts. While the embodiments of the present disclosure are susceptible to various modifications and alternative forms, specific embodiments thereof are shown by way of example in the drawings. However, the embodiments should not be construed as being limited to the embodiments set forth herein.

Hereinafter, various embodiments will be described with reference to the accompanying drawings. However, it should be understood that the embodiments of the present disclosure are not limited to specific embodiments, but include various modifications, equivalents and/or alternatives of the embodiments. The embodiments of the present disclosure may provide a variety of effects capable of being directly or indirectly recognized.

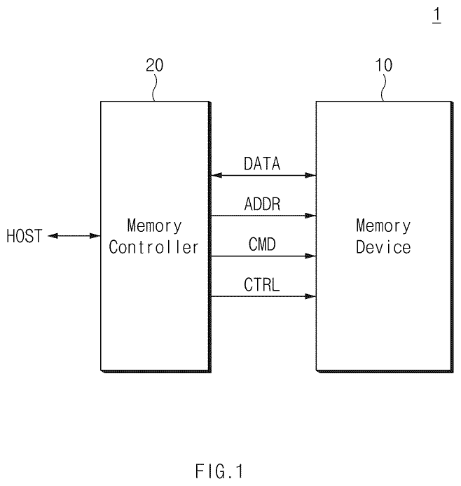

FIG. 1 is a block diagram illustrating an example of a memory system 1 based on some embodiments of the present disclosure.

Referring to FIG. 1, the memory system 1 may include a memory device 10 and a memory controller 20.

The memory system 1 may be implemented as an internal memory embedded in an electronic system (e.g., a smartphone, a tablet, a computer, a TV, etc.). For example, the memory system 1 may be an embedded universal flash storage (UFS), an embedded multimedia card (eMMC), or a solid state drive (SSD). According to one embodiment, the memory system 1 may be implemented as an external memory detachably coupled to an electronic device, and may be, for example, a UFS memory card, a compact flash (CF) card, a secure digital (SD) card, a micro-Secure Digital (micro-SD) card, a mini-Secure Digital (mini-SD) card, an extreme Digital (xD) card, or a memory stick.

The memory system 1 may store data received from a host in the memory device 10 based on an access request from the host, or may read data requested by the host from the memory device 10 and transmit the read data to the host.

The memory device 10 may include a plurality of memory cells, each of which stores data. According to one embodiment, each of the plurality of memory cells may be a nonvolatile memory cell that maintains stored data even when power supply is interrupted. For example, when the memory cell is a nonvolatile memory cell, the memory device 10 may be implemented as an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like. Hereinafter, embodiments of the present disclosure will be described as an example in which the plurality of memory cells is NAND flash memory cells, but the embodiments of the present disclosure are not limited thereto. The memory device 10 may perform program, read, and/or erase operations under control of the memory controller 20.

The memory controller 20 may provide a control signal (CTRL), a command (CMD), and an address (ADDR) to the memory device 10. The control signal (CTRL) may include information necessary for the memory device 10 to perform an operation corresponding to the command (CMD) received from the memory controller 20. For example, the control signal (CTRL) may include information about the sensing parameters necessary for the memory device 10 to read data from memory cells. The command (CMD) may indicate an operation to be performed by the memory device 10 during the program, read, or erase operation. The address (ADDR) may indicate a position at which the memory controller 20 desires to access data in the memory device 10. Data (DATA) may be transmitted and/or received between the memory controller 20 and the memory device 10 based on the command (CMD) and the address (ADDR).

The memory controller 20 may control various operations of the memory device 10 in response to an access request from the host, for example, the program operation for programming data (DATA) in the memory device 10, the read operation for reading data (DATA) from the memory device 10, and/or the erase operation for erasing data (DATA) of the memory device 10. For example, the memory controller 20 may transmit data (DATA) received from the host to the memory device 10 by executing a write command, or may transmit data (DATA) read from the memory device 10 to the host by executing a read command. In addition, the memory controller 20 may provide a clock signal, a chip selection signal, etc. to the memory device 10.

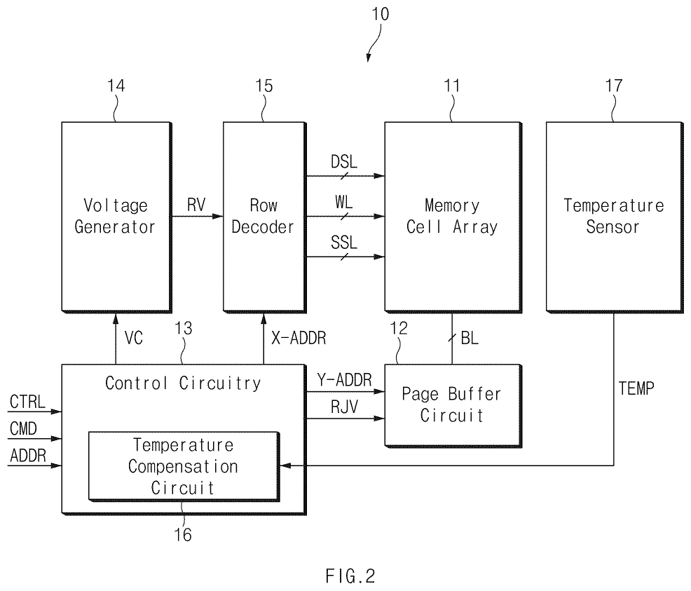

FIG. 2 is a block diagram illustrating the memory device 10 shown in FIG. 1 based on some embodiments of the present disclosure.

Referring to FIG. 2, the memory device 10 may include a memory cell array 11, a page buffer circuit 12, a control circuitry 13, a voltage generator 14, a row decoder 15, and a temperature sensor 17.

According to one embodiment, although not shown in FIG. 2, the memory device 10 may further include a data input/output (I/O) circuit for communication with an external device such as the memory controller 20, or an input/output (I/O) interface for communication with the external device.

The memory cell array 11 may include a plurality of memory cells. The memory cell array 11 may be connected to drain selection lines (DSLs), word lines (WLs), source selection lines (SSLs), and bit lines (BLs). The memory cell array 11 may be connected to a row decoder 15 through the drain selection lines (DSLs), the word lines (WLs), and the source selection lines (SSLs), and may be connected to a page buffer circuit 12 through the bit lines (BLs).

The memory cell array 11 may include a plurality of planes, each of which includes a plurality of memory blocks. Each memory block may include a plurality of memory cells arranged in a two-dimensional (2D) structure or a three-dimensional (3D) structure. The memory cell array 11 may include at least one of a single-level cell (SLC) block including single-level cells (SLCs), a multi-level cell (MLC) block including multi-level cells (MLCs), a triple-level cell (TLC) block including triple-level cells (TLCs), and a quad-level cell (QLC) block including quad-level cells (QLCs). For example, some of the plurality of memory blocks may be single-level cell (SLC) blocks, and other memory blocks may include multi-level cell (MLC) blocks, triple-level cell (TLC) blocks, or quad-level cell (QLC) blocks.

The page buffer circuit 12 may operate in response to a control signal of the control circuitry 13. The page buffer circuit 12 may select some bit lines among the bit lines (BLs) in response to a column address (Y-ADDR). For example, the page buffer circuit 12 may operate as a write driver or a sense amplifier.

According to one embodiment, during the program operation, the page buffer circuit 12 may operate as a write driver to apply a voltage according to data (DATA) to be stored in the memory cell array 11 to the bit lines (BLs). According to one embodiment, during the read operation, the page buffer circuit 12 may operate as a sense amplifier to detect data (DATA) stored in the memory cell array 11 received through the bit lines (BLs). The page buffer circuit 12 may detect data (DATA) using a read reference voltage (RJV) received from the control circuitry 13. For example, the page buffer circuit 12 may determine data (DATA) by comparing a voltage level of a signal received through the bit line (BL) with the read reference voltage (RJV).

The control circuitry 13 may output internal control signals for programming (writing) data (DATA) in the memory cell array 11 or reading data (DATA) from the memory cell array 11 based on the command (CMD), the address (ADDR), and the control signal (CTRL). For example, the control circuitry 13 may output a voltage control signal (VC) for controlling the levels of various reference voltages generated by the voltage generator 14.

The control circuitry 13 may include a temperature compensation circuit 16. The temperature compensation circuit 16 may perform temperature compensation based on temperature data (TEMP) received from the temperature sensor 17. In this case, the temperature compensation may refer to an operation of setting read conditions corresponding to temperature data (TEMP) to normally read data (DATA) stored in the memory cell array 11. The read conditions may include conditions on a read reference voltage (RJV), a pass voltage applied to unselected memory cells, a drain selection line voltage applied to a drain selection line (DSL), and/or a source selection line voltage applied to a source selection line (SSL).

According to one embodiment, the temperature compensation circuit 16 may output a voltage control signal (VC) so that the voltage generator 14 generates a reference voltage (RV) determined according to such temperature compensation. According to another embodiment, the temperature compensation circuit 16 may output a read reference voltage (RJV) determined according to the temperature compensation.

In FIG. 2, the control circuitry 13 is illustrated as including the temperature compensation circuit 16, but the scope or spirit of the embodiments of the present disclosure is not limited thereto, and the temperature compensation circuit 16 may be arranged outside the control circuitry 13. According to another embodiment, the temperature compensation circuit 16 may be included in the voltage generator 14 or implemented as a configuration independent of the control circuitry 13. Alternatively, the temperature compensation circuit 16 may be located outside the memory device 10 (e.g., as a part of the memory controller 20).

The control circuitry 13 may provide a row address (X-ADDR) for selecting the word line (WL) to the row decoder 15, and may provide a column address (Y-ADDR) for selecting the bit line (BL) to the page buffer circuit 12.

The voltage generator 14 may generate various types of reference voltages (RV) required to perform a program operation, a read operation, and an erase operation on the memory cell array 11 based on a voltage control signal (VC). Specifically, the voltage generator 14 may generate a word line voltage (e.g., a program voltage, a read voltage, a pass voltage, an erase verification voltage, or a program verification voltage) applied to a word line (WL), and may further generate a drain selection line voltage applied to a drain selection line (DSL) and a source selection line voltage applied to a source selection line (SSL). That is, the reference voltages (RV) may include a word line voltage, a drain selection line voltage, and a source selection line voltage.

The row decoder 15 may select one of a plurality of memory blocks in response to a row address (X-ADDR), and may select one of the word lines (WL) of the selected memory block. The row decoder 15 may supply voltages, required for a program operation, a read operation, or an erase operation for a memory cell connected to the selected word line (WL), to the word line (WL), the drain selection line (DSL), and the source selection line (SSL) using the reference voltages (RV).

The temperature sensor 17 may be arranged inside or adjacent to the memory cell array 11 to generate temperature data (TEMP) indicating the temperature of the memory cell array 11, and may transmit the temperature data (TEMP) to the temperature compensation circuit 16. According to one embodiment, the temperature sensor 17 may be any of an integrated circuit (IC) temperature sensor and a semiconductor temperature sensor, each of which includes a resistor having a resistance value that changes depending on the temperature and generates temperature data (TEMP) as a result of detecting the changed resistance value.

The memory device 10 may include a plurality of temperature sensors 17 to accurately measure the temperature of the memory cell array 11, and the arrangement and operation of the temperature sensors 17 will be described later.

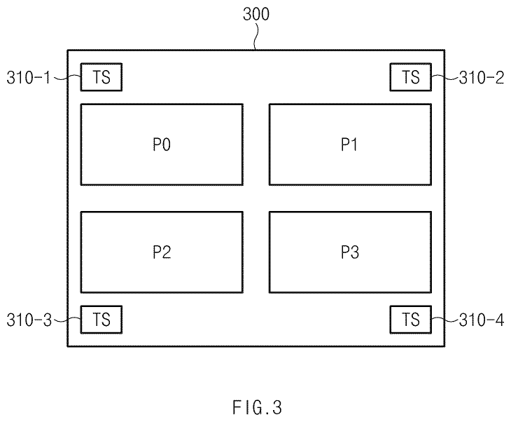

FIG. 3 is a schematic diagram illustrating a layout structure of the temperature sensors shown in FIG. 2 based on some embodiments of the present disclosure.

Referring to FIG. 3, the memory device 10 may be implemented as a chip, and one chip may include at least one die 300. The die 300 may include at least some of the components of the memory device 10, and is illustrated in FIG. 3 as including planes (P0˜P3) and temperature sensors (TSs) (310-1˜310-4), but the embodiments of the present disclosure are not limited thereto.

Specifically, the die 300 may include planes (P0˜P3) arranged in a matrix shape, and temperature sensors (310-1˜310-4) arranged to respectively correspond to the planes (P0˜P3).

Each of the planes (P0˜P3) may include a plurality of memory blocks, each of which includes a plurality of memory cells. In the present disclosure, for convenience of description, the memory cells included in the planes (P0˜P3) are single-level cells (SLC), but the technical concepts of the present disclosure may be substantially equally applied even when the memory cells included in the planes (P0˜P3) are multi-level cells (MLC), triple-level cells (TLC), and/or quad-level cells (QLC).

The first temperature sensor 310-1 may be arranged closest to the first plane (P0) among the planes (P0˜P3). The first temperature sensor 310-1 may measure the surrounding temperature to generate a first plane temperature value. As the first temperature sensor 310-1 is located closest to the first plane (P0), the first plane temperature value may represent the temperature of the first plane (P0).

The second temperature sensor 310-2 may be arranged closest to the second plane (P1) among the planes (P0˜P3). The second temperature sensor 310-2 may measure the surrounding temperature to generate a second plane temperature value. As the second temperature sensor 310-2 is arranged closest to the second plane (P1), the second plane temperature value may represent the temperature of the second plane (P1).

The third temperature sensor 310-3 may be arranged closest to the third plane (P2) among the planes (P0˜P3). The third temperature sensor 310-3 may measure the surrounding temperature to generate a third plane temperature value. As the third temperature sensor 310-3 is arranged closest to the third plane (P2), the third plane temperature value may represent the temperature of the third plane (P2).

The fourth temperature sensor 310-4 may be arranged closest to the fourth plane (P3) among the planes (P0˜P3). The fourth temperature sensor 310-4 may measure the surrounding temperature to generate a fourth plane temperature value. Since the fourth temperature sensor 310-4 is arranged closest to the fourth plane (P3), the fourth plane temperature value may represent the temperature of the fourth plane (P3).

The first to fourth plane temperature values may be included in the temperature data (TEMP) described in FIG. 2. That is, the first to fourth plane temperature values may be transmitted to the temperature compensation circuit 16.

In FIG. 3, each of the first to fourth temperature sensors (310-1˜310-4) is illustrated as being located closest to a corresponding vertex of the die 300 such that the first to fourth temperature sensors (310-1˜310-4) can be respectively located closest to the first to fourth planes (P0˜P3), but the embodiments of the present disclosure are not limited thereto. The positions of the first to fourth temperature sensors (310-1˜310-4) may vary as long as each of the first to fourth temperature sensors (310-1˜310-4) is located closest to the corresponding plane.

In addition, according to another embodiment, some of the first to fourth temperature sensors (310-1˜310-4) corresponding to the first to fourth planes (P0˜P3) may be omitted, so that temperature sensors corresponding to some of the first to fourth planes (P0˜P3) may not be arranged.

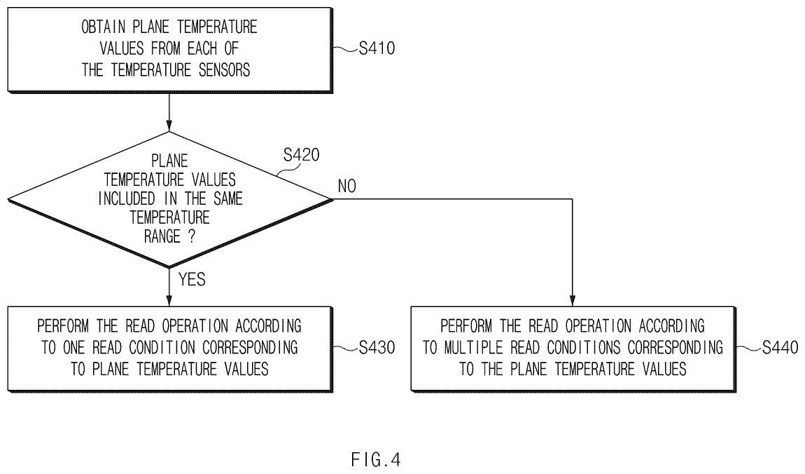

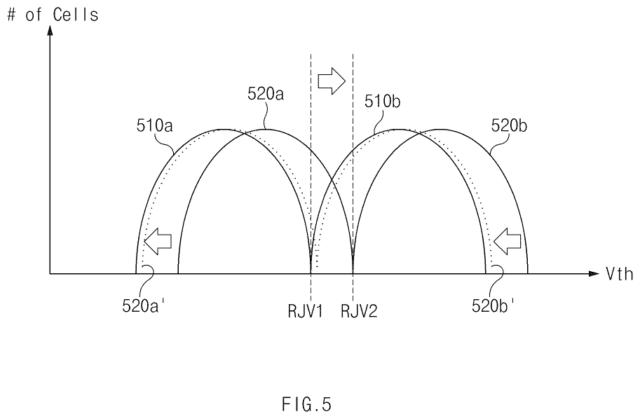

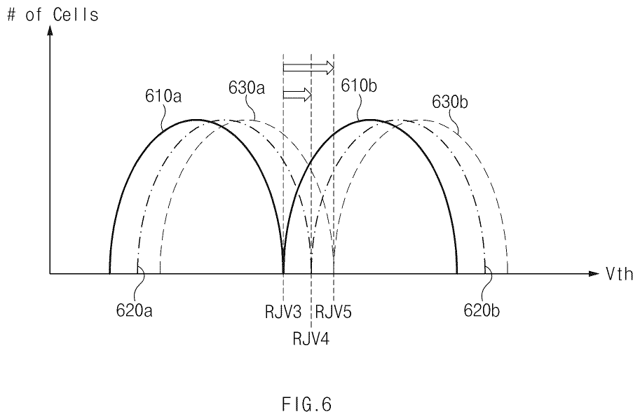

FIG. 4 is a flowchart illustrating a temperature compensation method of a memory device based on some embodiments of the present disclosure. FIG. 5 is a diagram illustrating operations according to operation S430 of FIG. 4 based on some embodiments of the present disclosure. FIG. 6 is a diagram illustrating operations according to operation S440 of FIG. 4 based some embodiments of the present disclosure.

Referring to FIG. 4, a temperature compensation method performed by the memory device 10 is illustrated, and the temperature compensation method of FIG. 4 will be described using the temperature compensation method for the die 300 shown in FIG. 3. The temperature compensation method of FIG. 4 may be a temperature compensation method for a case in which a read condition is independently applied to each of the first to fourth planes (P0˜P3).

The temperature compensation circuit 16 may obtain plane temperature values for the respective planes (P0˜P3) from the respective temperature sensors (310-1˜310-4) (S410).

The temperature compensation circuit 16 may determine whether the plane temperature values are included in the same temperature range (S420). The temperature compensation circuit 16 may manage temperature ranges, which are divided in units of a predetermined temperature interval from the entire temperature range of the plane temperature values output from the temperature sensors (310-1˜310-4). For example, the temperature ranges may include a first temperature range (20° C.˜30° C.), a second temperature range (30° C.˜40° C.), a third temperature range (40° C.˜50° C.), etc.

If the plane temperature values of the temperature sensors (310-1˜310-4) are included in the same temperature range (e.g., the second temperature range) (i.e., Yes in S420), the temperature compensation circuit 16 may control the elements within the memory device 10 to perform the read operation according to one read condition corresponding to the temperature range in which the plane temperature values are included (S430).

Referring to FIG. 5, a change in distribution of the memory cells according to a temperature change is illustrated. In the present disclosure, the distribution of the memory cells may refer to distribution (or dispersion) of threshold voltages of the memory cells.

The first distribution (510a, 510b) may correspond to distribution of memory cells included in each of the planes (P0˜P3) before the temperature increases, and the first distribution 510a may represent distribution of threshold voltages of memory cells that serve as turn-on cells (also called “On-Cells”) based on a first read reference voltage (RJV1), and the first distribution 510b may represent distribution of threshold voltages of memory cells that serve as turn-off cells (also called “OFF-Cells”) based on the first read reference voltage (RJV1).

The second distribution (520a, 520b) may correspond to distribution of memory cells included in each of the planes (P0˜P3) after the temperature increases, and the second distribution 520a may represent distribution of threshold voltages of memory cells that serve as turn-on cells (On-cells) based on a second read reference voltage (RJV2), and the second distribution 520b may represent distribution of threshold voltages of memory cells that serve as turn-off cells (Off-cells) based on the second read reference voltage (RJV2).

That is, the first distribution (510a, 510b) may shift to the d distribution (520a, 520b) according to the increasing second temperature. When the read operation is performed with the first read reference voltage (RJV1) on the memory cells having the second distribution (520a, 520b) even after the temperature rises, there may occur failure in which memory cells having a threshold voltage higher than the first read reference voltage (RJV1) from among the memory cells corresponding to the second distribution 520a are detected as off-cells.

To prevent this phenomenon, the temperature compensation circuit 16 may apply a read condition corresponding to a temperature range (e.g., a second temperature range) in which the plane temperature values are included. According to one embodiment, the temperature compensation circuit 16 may manage a table in which each temperature range and the read condition corresponding to each temperature range are matched to each other. For example, the temperature compensation circuit 16 may store a table in which temperature ranges and read conditions are matched to each other, or may access a table stored in an external part (e.g., the memory cell array 11 or the memory controller 20) to obtain the necessary read condition. The temperature compensation circuit 16 may control the read operation by matching a predetermined temperature range with the read conditions, and may thus reduce resources required for the table for the read condition and simplify the types of the read conditions.

According to one embodiment, the temperature compensation circuit 16 may control the read operation to be performed using the read reference voltage corresponding to the temperature range (e.g., the second temperature range) including the plane temperature values. The read reference voltage corresponding to the temperature range including the plane temperature values may increase as the temperature increases, and may decrease as the temperature decreases.

In FIG. 5, when the read reference voltage corresponding to the temperature range (e.g., the second temperature range) including the plane temperature values after the temperature increases, is the second read reference voltage (RJV2), the temperature compensation circuit 16 may provide the second read reference voltage (RJV2) as the read reference voltage (RJV) to the page buffer circuit 12. Accordingly, as the read operation is performed based on the second read reference voltage (RJV2), failure of the memory cells having the second distribution (520a, 520b) may be prevented.

According to one embodiment, the temperature compensation circuit 16 may control the read operation to be performed using the shift control voltage corresponding to the temperature range (e.g., the second temperature range) including the plane temperature values. Here, the shift control voltage may refer to a voltage applied to a peripheral transistor of a selected memory cell to move (or shift) the threshold voltage distribution of the memory cells to the left direction (in the direction in which the threshold voltage decreases) or to the right direction (in the direction in which the threshold voltage increases). The shift control voltage may include a pass voltage applied to unselected memory cells belonging to a NAND string including the selected memory cell, a drain selection voltage applied to a drain selection transistor belonging to the corresponding NAND string, and/or a source select voltage applied to a source selection transistor belonging to the corresponding NAND string. That is, the shift control voltage may be a part of the reference voltages (RV). The drain selection transistor may be connected between the bit line (BL) and each of the memory cells connected in series, and the source selection transistor may be connected between a source line and each of memory cells connected in series.

When the pass voltage, the drain selection voltage, and/or the source selection voltage increase, the threshold voltage distribution of the selected memory cell may shift to the right due to a change in electric potential. Conversely, when the pass voltage, the drain selection voltage, and/or the source selection voltage decrease, the threshold voltage distribution of the selected memory cell may shift to the left due to a change in electric potential.

The shift control voltage corresponding to the temperature range in which the plane temperature values are included may decrease as the temperature increases and may increase as the temperature decreases.

In FIG. 5, when the shift control voltage corresponding to the temperature range (e.g., the second temperature range) including the plane temperature values after the temperature increases is a specific shift control voltage, the temperature compensation circuit 16 may provide the voltage generator 14 with a voltage control signal (VC) that is used to generate a reference voltage (RV) corresponding to the specific shift control voltage and to supply the reference voltage (RV) to the corresponding plane. The specific shift control voltage may be a voltage for shifting the second distribution (520a, 520b) to the second distribution (520a′, 520b′) that is substantially the same as the first distribution (510a, 510b). Accordingly, even if the read operation is performed based on the first read reference voltage (RJV1), as the memory cells having the second distribution (520a, 520b) are shifted to the second distribution (520a′, 520b′), failure of the memory cells can be prevented.

The voltage control signal for controlling the read reference voltage and the shift control voltage described in FIG. 5 may be collectively referred to as a read control signal that is generated by the temperature compensation circuit 16 to perform the read operation on each of the planes (P0˜P3).

Referring back to FIG. 4, when the plane temperature values of the temperature sensors (310-1˜310-4) are included in different temperature ranges (e.g., the second temperature range and the third temperature range) (i.e., No in S420), the temperature compensation circuit 16 may control the elements within the memory device 10 to perform the read operation according to a plurality of read conditions respectively corresponding to the different temperature ranges in which the plane temperature values are included (S440).

Referring to FIG. 6, a change in distribution of the memory cells according to a temperature change is illustrated.

The third distribution (610a, 610b) may correspond to distribution of memory cells included in the planes (P0˜P3) before the temperature increases, and the third distribution 610a may represent distribution of threshold voltages of memory cells that can serve as the ON-cells (i.e., turn-on cells) based on the third read reference voltage (RJV3), and the third distribution 610b may represent distribution of threshold voltages of memory cells that can serve as the OFF-cells (i.e., turn-off cells) based on the third read reference voltage (RJV3).

The fourth distribution (620a, 620b) may correspond to distribution of memory cells included in some planes (e.g., P0˜P2) after the temperature increases, and the fourth distribution 620a may represent distribution of threshold voltages of memory cells that can serve as the on-cells (i.e., turn-on cells) based on the fourth read reference voltage (RJV4), and the fourth distribution 620b may represent distribution of threshold voltages of memory cells that can serve as the off-cells (i.e., turn-off cells) based on the fourth read reference voltage (RJV4).

The fifth distribution (630a, 630b) may correspond to distribution of memory cells included in the remaining planes (e.g., P3) after the temperature increases, and the fifth distribution 630a may represent distribution of threshold voltages of memory cells that can serve as the on-cells (i.e., turn-on cells) based on the fifth read reference voltage (RJV5), and the fifth distribution 630b may represent distribution of threshold voltages of memory cells that can serve as the off-cells (i.e., turn-off cells) based on the fifth read reference voltage (RJV5).

The increased amounts of temperatures in some planes (e.g., P0˜P2) may be smaller than the increased amounts of temperatures in the remaining planes (e.g., P3), and the plane temperature values for some planes (e.g., P0˜P2) may be smaller than the plane temperature values for the remaining planes (e.g., P3).

The third distribution (610a, 610b) may shift to the fourth distribution (620a, 620b) or the fifth distribution (630a, 630b) depending on the temperature increase. Whereas the planes (P0˜P3) are disposed on the same die 300, depending on the arrangement of the planes, distribution of the memory cells included in the plane (e.g., P3) that is arranged adjacent to an integrated circuit (IC) with relatively high heat generation may shift to the fifth distribution (630a, 630b), or distribution of the memory cells included in the plane (e.g., P0˜P2) that is arranged distant to the integrated circuit (IC) with relatively high heat generation may shift to the fourth distribution (620a, 620b).

If the read operation is performed with the third read reference voltage (RJV3) on the memory cells having the fourth distribution (620a, 620b) or the fifth distribution (630a, 630b) even after the temperature increases, there may occur a failure in which memory cells having a threshold voltage higher than the third read reference voltage (RJV3) from among the memory cells corresponding to the fourth distribution 620a or the fifth distribution 630a are detected as the off-cells.

To prevent this phenomenon, the temperature compensation circuit 16 may apply a read condition corresponding to a temperature range (e.g., a second temperature range or a third temperature range) including the plane temperature values to each plane. According to one embodiment, the temperature compensation circuit 16 may manage a table in which each temperature range and the read condition corresponding to each temperature range are matched to each other. For example, the temperature compensation circuit 16 may store a table in which the temperature range and the read condition are matched to each other, or may access a table stored in the external device (e.g., a memory cell array 11 or a memory controller 20) to obtain the necessary read condition.

According to one embodiment, the temperature compensation circuit 16 may control a read operation for a plane corresponding to each plane temperature value to be performed using a read reference voltage corresponding to a temperature range (e.g., a second temperature range) in which each plane temperature value is included.

In FIG. 6, when the read reference voltage corresponding to a temperature range (e.g., a second temperature range) including plane temperature values for some planes (e.g., P0˜P2) after the temperature increases is the fourth read reference voltage (RJV4), the temperature compensation circuit 16 may provide the page buffer circuit 12 with the fourth read reference voltage (RJV4) as the read reference voltage (RJV) for some planes (e.g., P0˜P2).

Accordingly, since the read operation is performed based on the fourth read reference voltage (RJV4) for some planes (e.g., P0˜P2), failure of the memory cells having the fourth distribution (620a, 620b) may be prevented.

In addition, when the read reference voltage corresponding to the temperature range (e.g., the third temperature range) in which the plane temperature value for the remaining planes (e.g., P3) is included after the temperature increases is the fifth read reference voltage (RJV5), the temperature compensation circuit 16 may provide the page buffer circuit 12 with the fifth read reference voltage (RJV5) as the read reference voltage (RJV) for the remaining planes (e.g., P3).

Accordingly, since the read operation is performed based on the fifth read reference voltage (RJV5) for the remaining planes (e.g., P3), failure of the memory cells having the fifth distribution (630a, 630b) may be prevented.

Although a method for performing temperature compensation for the read operation using the read reference voltage has been described with reference to FIG. 6, temperature compensation for the read operation may also be performed using a shift control voltage as described with reference to FIG. 5.

That is, the temperature compensation circuit 16 may generate a reference voltage (RV) corresponding to a shift control voltage for shifting the fourth distribution (620a, 620b) to substantially the same distribution as the third distribution (610a, 610b), and may provide a voltage control signal (VC) to the voltage generator 14 to supply the reference voltage (RV) to the corresponding plane (e.g., P0˜P2). In addition, the temperature compensation circuit 16 may provide a voltage control signal (VC) to the voltage generator 14, such that the temperature compensation circuit 16 can generate a reference voltage (RV) corresponding to a shift control voltage for shifting the fifth distribution (630a, 630b) to substantially the same distribution as the third distribution (610a, 610b) and can supply the reference voltage (RV) to the corresponding plane (e.g., P3).

Accordingly, even if the read operation is performed based on the third read reference voltage (RJV3), memory cells having the fourth distribution (620a, 620b) or the fifth distribution (630a, 630b) are shifted to substantially the same distribution as the third distribution (610a, 610b), so that failure of the memory cells can be prevented.

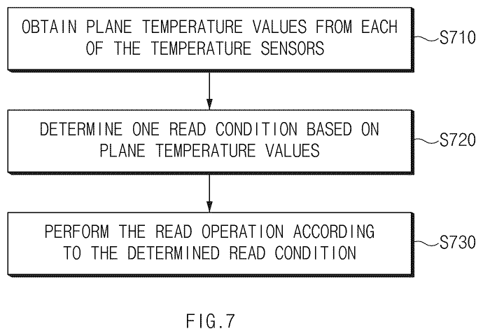

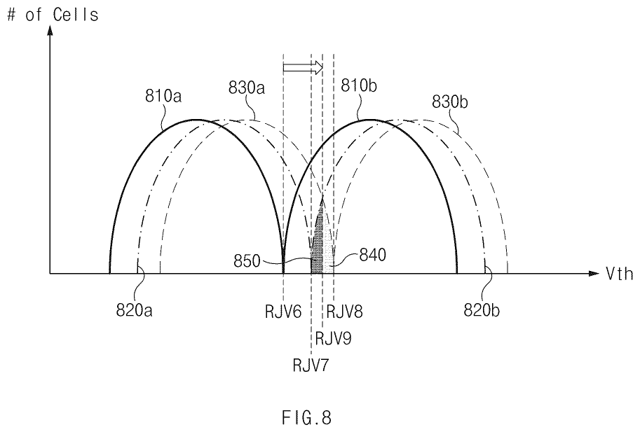

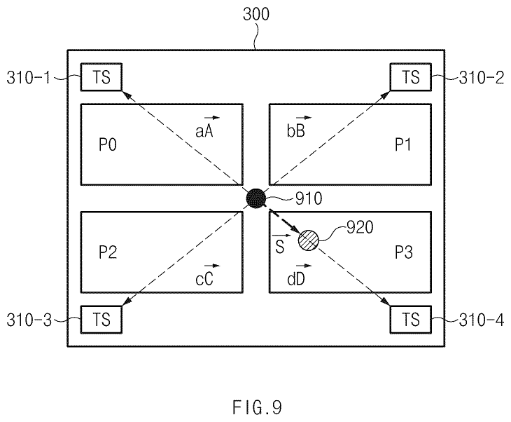

FIG. 7 is a flowchart illustrating a temperature compensation method of a memory device based on some other embodiments of the present disclosure. FIG. 8 is a diagram illustrating operations according to operation S720 of FIG. 7. FIG. 9 is a schematic diagram illustrating a method for calculating a representative temperature value described in FIG. 8.

Referring to FIG. 7, another embodiment of a temperature compensation method performed by the memory device 10 is illustrated, and a temperature compensation method for the die 300 illustrated in FIG. 3 will be described. The temperature compensation method of FIG. 7 may be a temperature compensation method for an example case in which a single read condition is applied to each of the first to fourth planes (P0˜P3) without independently applying the read condition to each of the first to fourth planes (P0˜P3).

The temperature compensation circuit 16 may obtain plane temperature values for the respective planes (P0˜P3) from the respective temperature sensors (310-1˜310-4) (S710).

The temperature compensation circuit 16 may determine one read condition based on the plane temperature values (S720).

Referring to FIG. 8, the change in distribution of memory cells according to the temperature change is illustrated.

The sixth distribution (810a, 810b) may correspond to distribution of memory cells included in the plane (P0˜P3) before the temperature increases, and the sixth distribution 810a may represent distribution of threshold voltages of memory cells that can serve as the on-cells based on the sixth read reference voltage (RJV6), and the sixth distribution 810b may represent distribution of threshold voltages of memory cells that can serve as the off-cells based on the sixth read reference voltage (RJV6).

The seventh distribution (820a, 820b) may correspond to distribution of memory cells included in some planes (e.g., P0˜P2) after the temperature increases, and the seventh distribution 820a may represent distribution of threshold voltages of memory cells that can serve as the on-cells based on the seventh read reference voltage (RJV7), and the seventh distribution 820b may represent distribution of threshold voltages of memory cells that can serve as the off-cells based on the seventh read reference voltage (RJV7).

The eighth distribution (830a, 830b) may correspond to distribution of memory cells included in the remaining plane (e.g., P3) after the temperature increases, and the eighth distribution 830a may represent distribution of threshold voltages of memory cells that can serve as the on-cells based on the eighth read reference voltage (RJV8), and the eighth distribution 830b may represent distribution of threshold voltages of memory cells that can serve as the off-cells based on the eighth read reference voltage (RJV8).

That is, the sixth distribution (810a, 810b) may shift to the seventh distribution (820a, 820b) or the eighth distribution (830a, 830b) depending on the increasing temperature. If the read operation is performed using the sixth read reference voltage (RJV6) for memory cells having the seventh distribution (820a, 820b) or the eighth distribution (830a, 830b) even after the temperature increases, there may occur failure in which memory cells having a threshold voltage higher than the sixth read reference voltage (RJV6) from among the memory cells corresponding to the seventh distribution (820a, 820b) or the eighth distribution (830a, 830b) are detected as the off-cells.

The temperature compensation circuit 16 may calculate a representative temperature value by calculating the plane temperature values obtained from the temperature sensors (310-1˜310-4). The representative temperature value may refer to a value representing the plane temperature values obtained from the temperature sensors (310-1˜310-4) included in the die 300. According to one embodiment, the temperature compensation circuit 16 may calculate the representative temperature value by calculating the average value of the plane temperature values obtained from the temperature sensors (310-1˜310-4). According to another embodiment, the temperature compensation circuit 16 may calculate the representative temperature value by calculating a median value of the plane temperature values obtained from the temperature sensors (310-1˜310-4).

Another embodiment of calculating the representative temperature value by the temperature compensation circuit 16 will be described with reference to FIG. 9. FIG. 9 illustrates the die 300 described with reference to FIG. 3, and a temperature center 910 of the first to fourth temperature sensors (310-1˜310-4).

The temperature center 910 may refer to a center of gravity of a polygon (e.g., a square in FIG. 9) formed by the first to fourth temperature sensors (310-1˜310-4). The temperature center 910 may be a reference point for determining a weight to be applied when calculating the representative temperature value.

The temperature compensation circuit 16 may calculate a reference temperature value by calculating the plane temperature values obtained from the temperature sensors (310-1˜310-4). For example, the reference temperature value may be an average value or a median value of the plane temperature values. The temperature compensation circuit 16 may calculate a temperature weight based on the positions of the temperature sensors (310-1˜310-4) and the plane temperature values.

The temperature compensation circuit 16 may calculate first to fourth vectors commonly having, as an initial point, the temperature center 910 of the temperature sensors (310-1˜310-4) and each having a terminal point directed to a corresponding one of the temperature sensors (310-1˜310-4) based on the positions of the temperature sensors (310-1˜310-4) and the plane temperature values of the temperature sensors (310-1˜310-4), and may calculate a sum vector(S) which is the sum of the first to fourth vectors. The sum vector(S) may be represented by the following equation 1.

$$\vec{S} = a \vec{A} + b \vec{B} + c \vec{C} + d \vec{D} \qquad [ Equation 1 ]$$

In Equation 1, the first vector may be the product of the plane temperature value (a) of the temperature sensor 310-1 and a unit vector (A) having a direction from the temperature center 910 toward the temperature sensor 310-1. The second vector may be the product of the plane temperature value (b) of the temperature sensor 310-2 and a unit vector (B) having a direction from the temperature center 910 toward the temperature sensor 310-2. The third vector may be the product of the plane temperature value (c) of the temperature sensor 310-3 and a unit vector (C) having a direction from the temperature center 910 toward the temperature sensor 310-3. The fourth vector may be the product of the plane temperature value (d) of the temperature sensor 310-4 and a unit vector (D) having a direction from the temperature center 910 toward the temperature sensor 310-4.

The sum vector(S) may represent the direction and magnitude (i.e., distance) of movement of the temperature center 910 in consideration of the positions of the temperature sensors (310-1˜310-4) and the plane temperature values. In FIG. 9, the plane temperature values of the temperature sensors (310-1˜310-3) are equal to each other, and the plane temperature value of the temperature sensor 310-4 is higher than the plane temperature values of the temperature sensors (310-1˜310-3). Accordingly, the sum vector(S) may have a direction toward the temperature sensor 310-4 and a magnitude of a predetermined scalar value. That is, the temperature center 910 may move to the temperature center 920 changed by the sum vector(S).

When the plane temperature value of a specific temperature sensor (e.g., 310-4) is significantly different from other plane temperature values, the magnitude of the sum vector(S) may represent a difference between the plane temperature value of the specific temperature sensor (e.g., 310-4) and other plane temperature values.

The temperature compensation circuit 16 may calculate a temperature weight by using the magnitude of the sum vector(S) calculated based on the positions and plane temperature values of the temperature sensors (310-1˜310-4). According to one embodiment, the temperature compensation circuit 16 may calculate the temperature weight by scaling down the magnitude of the sum vector (S). For example, scaling down may mean an operation of converting the magnitude of the sum vector(S) into a temperature weight having a range of 1.0 to 1.5. Here, the range of the temperature weight may be experimentally determined according to performance of an error correction code (ECC) circuit (not shown). Additionally, the magnitude of the sum vector(S) and the temperature weight may be proportional to each other.

The temperature compensation circuit 16 may calculate a representative temperature value by calculating (e.g., multiplying) the reference temperature value and the temperature weight. That is, unlike the embodiments in which the average or median value described above is used as the representative temperature value, the present embodiment reflects the temperature weight in the representative temperature value, when the plane temperature value of a specific temperature sensor is significantly higher or lower than most of the plane temperature values, the possibility of occurrence of an uncorrectable error correction code (UECC) error in which the number of errors detected in a plane corresponding to a specific temperature sensor exceeds the error correction capacity so that such errors are not corrected based on the ECC error correction operation of the ECC circuit (not shown) may be reduced.

Referring back to FIG. 8, the temperature compensation circuit 16 may determine the read condition corresponding to the representative temperature value. According to one embodiment, the temperature compensation circuit 16 may manage a table in which the representative temperature value and the read condition corresponding to the representative temperature value are matched to each other. For example, the temperature compensation circuit 16 may store a table in which the representative temperature value and the read condition are matched to each other or may access a table stored in the external device (e.g., the memory cell array 11 or the memory controller 20) to obtain necessary read conditions.

In FIG. 8, the temperature compensation circuit 16 may calculate (e.g., average) the plane temperature values for some planes (e.g., P0˜P2) and the plane temperature values for the remaining planes (e.g., P3), and may thus calculate a representative temperature value. The representative temperature value may be greater than the plane temperature values for some planes (e.g., P0˜P2) and may be less than the plane temperature values for the remaining planes (e.g., P3). Accordingly, the ninth read reference voltage (RJV9) corresponding to the representative temperature value may be greater than the seventh read reference voltage (RJV7) corresponding to the plane temperature values for some planes (e.g., P0˜P2), and may be less than the eighth read reference voltage (RJV8) corresponding to the plane temperature values for the remaining planes (e.g., P3).

If the read operation is performed with the seventh read reference voltage (RJV7) on the memory cells having the seventh distribution (820a, 820b) or the eighth distribution (830a, 830b), there may occur failure in which memory cells having a threshold voltage higher than the seventh read reference voltage (RJV7) from among the memory cells corresponding to the eighth distribution 830a are detected as the off-cells. Alternatively, if the read operation is performed with the eighth read reference voltage (RJV8) on memory cells having the seventh distribution (820a, 820b) or the eighth distribution (830a, 830b), there may occur failure in which memory cells having a threshold voltage lower than the eighth read reference voltage (RJV8) from among the memory cells corresponding to the seventh distribution 820b are detected as the on-cells. At this time, the ratio of memory cells in which failure occurs in each distribution may be relatively high, which may cause UECC errors to occur.

In the present disclosure, the temperature compensation circuit 16 may determine the ninth read reference voltage (RJV9) corresponding to the representative temperature value as the read condition. The ninth read reference voltage (RJV9) may be greater than the seventh read reference voltage (RJV7), and may be less than the eighth read reference voltage (RJV8).

When the read operation is performed with the ninth read reference voltage (RJV9) on memory cells having the seventh distribution (820a, 820b) or the eighth distribution (830a, 830b), there may occur failure in which the memory cells 840 having a threshold voltage higher than the ninth read reference voltage (RJV9) from among the memory cells corresponding to the eighth distribution 830a are detected as the off-cells, and there may also occur failure in which the memory cells 850 having a threshold voltage less than the ninth read reference voltage (RJV9) from among the memory cells corresponding to the seventh distribution 820b are detected as the on-cells. At this time, the ratio of memory cells in which failure occurs in each distribution may be relatively low, and thus the detected error may not exceed the error correction capacity, so that the possibility of UECC error occurrence may be significantly reduced.

Although a method for performing temperature compensation for the read operation using the read reference voltage has been described with reference to FIG. 8, temperature compensation for the read operation may also be performed using a shift control voltage as described with reference to FIG. 5.

Referring back to FIG. 7, the temperature compensation circuit 16 may control the elements within the memory device 10 to perform the read operation according to the determined read condition (S730).

According to the embodiments of the present disclosure, the performance of the read operation can be improved by setting the read condition using temperature information obtained from a plurality of temperature sensors arranged adjacent to each plane (P0˜P3) included in the die 300.

As is apparent from the above description, the semiconductor memory device according to the embodiments of the present disclosure can improve performance of a read operation by setting a read condition using temperature information obtained from a plurality of temperature sensors arranged adjacent to each plane of the semiconductor memory device.

The embodiments of the present disclosure may provide a variety of advantageous effects capable of being directly or indirectly recognized through the above-mentioned embodiments.

Those skilled in the art will appreciate that concepts of the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Furthermore, the embodiments may be combined to form additional embodiments.

What is claimed is:

1. A semiconductor memory device comprising:
a die including a plurality of planes each having a plurality of memory cells;
a plurality of temperature sensors arranged in the die and arranged to correspond to respective planes; and
a temperature compensation circuit configured to generate, based on plane temperature values obtained from the plurality of temperature sensors respectively, a read control signal for performing a read operation on each of the plurality of planes.

2. The semiconductor memory device according to claim 1, wherein
each of the plurality of temperature sensors is arranged closest to a corresponding one of the plurality of planes than other planes.

3. The semiconductor memory device according to claim 1, wherein:
the plurality of planes are arranged in a matrix shape, and
each of the plurality of temperature sensors is arranged closest to a corresponding one of vertices of the die than other vertices.

4. The semiconductor memory device according to claim 1, wherein
the read control signal includes a read reference voltage for determining data.

5. The semiconductor memory device according to claim 4, further comprising:
a page buffer circuit configured to determine the data by comparing a voltage level of a signal transmitted through a bit line with the read reference voltage.

6. The semiconductor memory device according to claim 1, wherein
the read control signal includes a voltage control signal for controlling levels of shift control voltages required to shift a threshold voltage distribution of the memory cells.

7. The semiconductor memory device according to claim 6, further comprising:
a voltage generator configured to generate the shift control voltage based on the voltage control signal.

8. The semiconductor memory device according to claim 6, wherein the shift control voltage includes:
a word line voltage to be applied to a word line,
a drain selection line voltage to be applied to a drain selection line, and
a source selection line voltage to be applied to a source selection line.

9. The semiconductor memory device according to claim 1, wherein
when the plane temperature values are included in a single temperature range, the temperature compensation circuit generates one read control signal corresponding to the single temperature range.

10. The semiconductor memory device according to claim 1, wherein
when the plane temperature values are included in different temperature ranges, the temperature compensation circuit generates a plurality of read control signals corresponding to the respective temperature ranges.

11. The semiconductor memory device according to claim 10, wherein
a read reference voltage to be utilized for the read operation on a plane corresponding to a plane temperature value included in a first temperature range is lower than a read reference voltage to be utilized for the read operation on a plane corresponding to a plane temperature value included in a second temperature range higher than the first temperature range.

12. The semiconductor memory device according to claim 10, wherein
a shift control voltage to be utilized to shift a threshold voltage distribution of the memory cells in a plane corresponding to a plane temperature value included in a first temperature range is higher than a shift control voltage to be utilized to shift a threshold voltage distribution of the memory cells in a plane corresponding to a plane temperature value included in a second temperature range higher than the first temperature range.

13. The semiconductor memory device according to claim 1, wherein the temperature compensation circuit is configured to:
calculate a representative temperature value by calculating the plane temperature values, and
generate the read control signal corresponding to the representative temperature value.

14. The semiconductor memory device according to claim 13, wherein
the representative temperature value is an average value of the plane temperature values.

15. The semiconductor memory device according to claim 13, wherein
the representative temperature value is a median value of the plane temperature values.

16. The semiconductor memory device according to claim 13, wherein
the representative temperature value is a product of a reference temperature value, which is an average or median value of the plane temperature values, and a temperature weight.

17. The semiconductor memory device according to claim 16, wherein
the temperature weight is calculated based on a magnitude of a sum vector obtained by summing a plurality of vectors commonly having, as an initial point, a center of gravity of a polygon formed by the plurality of temperature sensors and each having a terminal point directed to a corresponding one of the plurality of temperature sensors.

18. The semiconductor memory device according to claim 17, wherein
each of the plurality of vectors has a magnitude of a plane temperature value obtained from the corresponding temperature sensor.

19. A semiconductor memory device comprising:
a plurality of planes, each of which includes a plurality of memory cells;
a plurality of temperature sensors arranged corresponding to the respective planes;
a temperature compensation circuit configured to generate, based on plane temperature values obtained from the respective temperature sensors, a read reference voltage for performing a read operation on each of the plurality of planes; and
a page buffer circuit configured to determine data by comparing a voltage level of a signal transmitted through a bit line connected to the plurality of planes with the read reference voltage.

20. A semiconductor memory device comprising:
a plurality of planes, each of which includes a plurality of memory cells;
a plurality of temperature sensors arranged to correspond to the respective planes;
a temperature compensation circuit configured to generate, based on plane temperature values obtained from the respective temperature sensors, a voltage control signal for controlling levels of shift control voltages required to shift a threshold voltage distribution of the memory cells; and
a voltage generator configured to generate the shift control voltage based on the voltage control signal.
